(19) United States
(12) Patent Application Publication
(10) Pub. No.: US 2009/0179326 A1
(43) Pub. Date: Jul. 16, 2009

(54) SEMICONDUCTOR DEVICE PACKAGE

(75) Inventors: Ko-Yang Tso, Hsinchu County (TW); Chung-Cheng Chou, Taoyuan County (TW); William Wang, Taoyuan County (TW); Chia-Hung Hsu, Taipei County (TW)

Correspondence Address: QUINTERO LAW OFFICE, PC, 2210 MAIN STREET, SUITE 200, SANTA MONICA, CA, 90405, US

(73) Assignee: RAYDIUM SEMICONDUCTOR CORPORATION, Hsinchu (TW)

(21) Appl. No.: 12/106,148

(22) Filed: Apr. 18, 2008

(30) Foreign Application Priority Data
Jan. 15, 2008 (TW) TW97101449

(51) Int. Cl. H01L 23/49

(52) U.S. Cl. 257/737; 257/784; 257/E23.024

(57) ABSTRACT

The invention provides a semiconductor device package. The package includes a chip disposed on a supported board and a conductive path formed between the chip and the supported board, on the backside of the supported board, or on the chip, so that the conductive path does not have to go around a region where the chip is located. Accordingly, the dimensions of the semiconductor device package are reduced.

### BACKGROUND OF THE INVENTION

1. Field of the Invention

The invention relates to a semiconductor device package, and more particularly to a semiconductor device package with reduced dimensions.

2. Description of the Related Art

The semiconductor device fabrication process includes a necessary packaging step for semiconductor devices to be applied in a variety of electric devices, for example computers, digital cameras or mobile phones. As the semiconductor device functions increase and improve, is getting better and various, the density of semiconductor device signal pins increase, resulting in an enlarged semiconductor device package.

FIG. 1 is a top view of a conventional semiconductor device package. In FIG. 1, a chip 4 is placed on a printed circuit board (PCB) 2, and a bonding pad 8 formed on the chip 2 is electrically connected to a bonding pad 6 formed on the printed circuit board 2 to transmit a signal from the chip 4. A trace 10, electrically connecting to the bonding pad 6, is formed on the printed circuit board 2 and the trace 10 goes around a region where the chip 4 is located, then to an exterior circuit (not shown) to transmit the signal. Thus, due to the trace 10 going around the chip 4, the area of the printed circuit board 2 is enlarged, as A shows in FIG. 1. Accordingly, the dimensions of the semiconductor device package are increased.

Thus, a semiconductor device package is required eliminating the above-described problems.

### BRIEF SUMMARY OF INVENTION

Accordingly, the invention provides a semiconductor device package. An exemplary embodiment of the semiconductor device package, includes: a supported board having a first conductive layer and a second conductive layer formed thereon; and a chip having a first bonding pad and a second bonding pad formed thereon disposed on the supported board, and the first bonding pad and the second bonding pad electrically connected to the first conductive layer and the second conductive layer, respectively. The second conductive layer is between the chip and the supported board. The second conductive layer, serving to as a conductive path for a signal, is formed under the chip, without going around a region where the chip is located. Thus, decreasing the area of the supported board used to support the conductive path. Accordingly, the dimensions of the semiconductor device package are reduced.

An exemplary embodiment of the semiconductor device package, includes: a supported board having a first surface and a second surface opposite to the first surface; a chip having a first bonding pad and a second bonding pad formed thereon disposed on the first surface of the supported board; a first conductive layer formed on the first surface of the supported board and electrically connected to the first bonding pad; and a second conductive layer formed on the second surface of the supported board and electrically connected to the second bonding pad. The second conductive layer for transmitting signals can be formed on the backside (the second surface) of the supported board, rather than going around a region where the chip is located. Thus, increasing utilization efficiency of the supported board used to support the conductive layer. Accordingly, the dimensions of the semiconductor device package are reduced.

Another exemplary embodiment of the semiconductor device package, includes: a supported board having a first conductive layer and a second conductive layer; a chip having a semiconductor device fabricated therein disposed on the supported board; a third conductive layer formed on the chip and electrically connected to the semiconductor device; a first bonding pad formed on the chip and electrically connected to the first conductive layer; and a second bonding pad formed on the third conductive layer and electrically connected to the second conductive layer. The second bonding pad and the first bonding pad are located on the same side. A signal from the chip can be transmitted to one side of the chip via the third conductive layer formed on the chip. Thus, decreasing the area of the supported board used to support the conductive path. Accordingly, the dimensions of the semiconductor device package are reduced.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1. is a top view of a conventional semiconductor device package;

FIGS. 2A and 2C-2D are schematic views of a semiconductor device package according to a first embodiment of the invention;

FIG. 2B is a cross section of a semiconductor device package according to a second embodiment of the invention;

FIG. 3A is a cross section of a semiconductor device package according to a third embodiment of the invention;

FIG. 3B is a cross section of a semiconductor device package according to a fourth embodiment of the invention;

FIGS. 4A-4B are schematic views of a semiconductor device package according to a fifth embodiment of the invention; and

FIG. 5 is a cross section of a semiconductor device package according to a sixth embodiment of the invention.

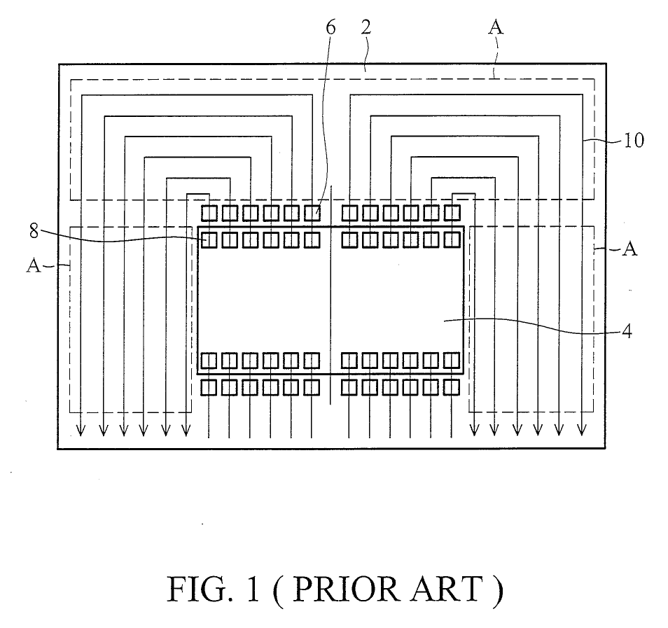

### DETAILED DESCRIPTION OF INVENTION

The following description is of the embodiments of carrying out the invention. This description is made for the purpose of illustrating the general principles of the invention and should not be taken in a limiting sense. The scope of the invention is best determined by reference to the appended claims.

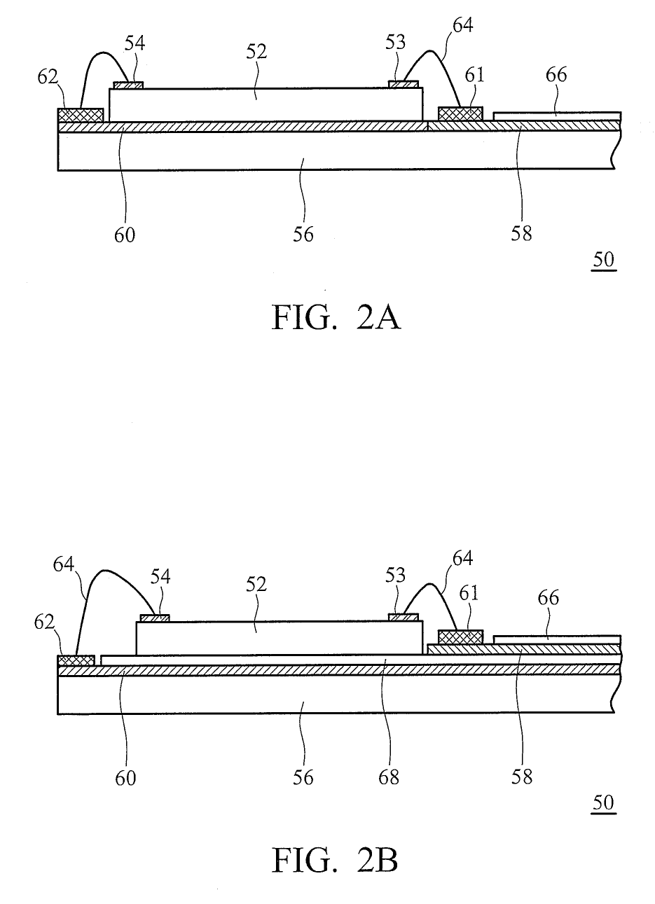

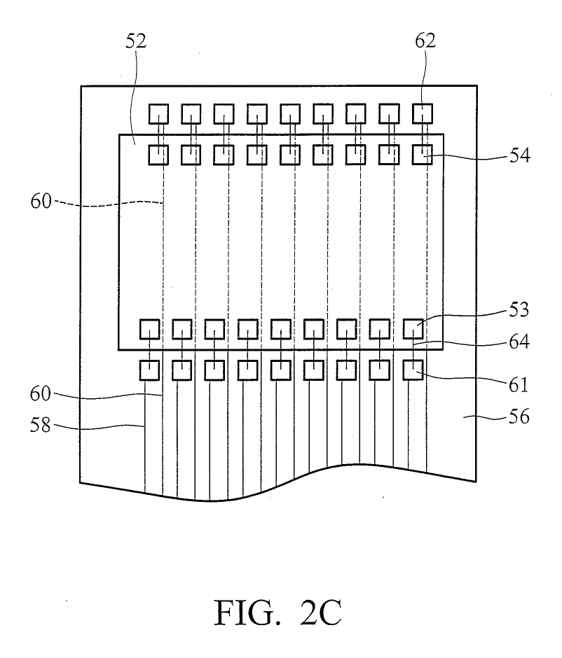

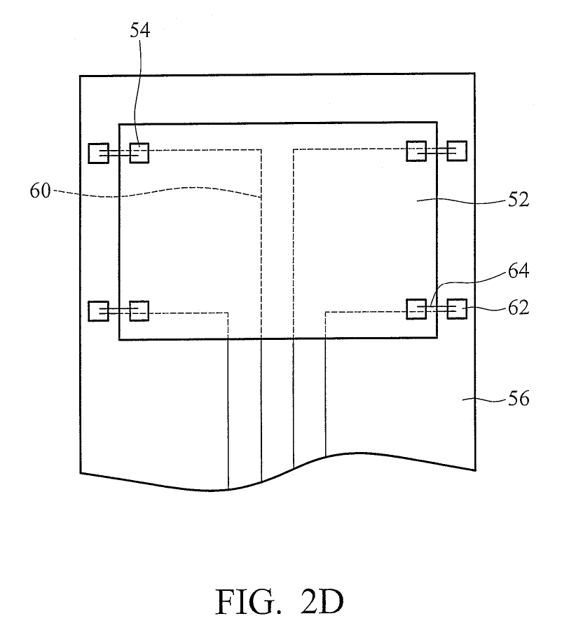

FIGS. 2A to 2D are schematic views of a semiconductor device package 50 according to several embodiments of the invention, in which a conductive path extends under a chip. FIG. 2A is a cross section of a semiconductor device package 50 according to a first embodiment of the invention. In FIG. 2A, a supported board 56, also referred to as a printed circuit board (PCB) or a supported substrate, is provided with a conductive layer 58 and a conductive layer 60 formed thereon. A bonding pad 61 and a bonding pad 62 are respectively formed on the conductive layer 58 and the conductive layer 60 to electrically connect thereto. A chip 52, having a bonding pad 53 and a bonding pad 54, is disposed on the conductive layer 60 of the supported board 56. Using a wire 64, the bonding pad 53 is electrically connected to the bonding pad 61, and the bonding pad 54 is electrically connected to the bonding pad 62. Specifically, in this case, the conductive layer 60 is formed between the chip 52 and the supported board 56, and extends to an exterior circuit (not shown) to transmit a signal from the chip 52. The bonding pads 53, 54, 61 and 62 may also be referred to as input/output pins.

In one embodiment, the supported board 56, such as a substrate consisting of a multilayer of glass fibers and epoxy, is provided, and a conductive material layer (not shown), such as copper (Cu) or other suitable conductive materials, is then deposited on the supported board 56 by a chemical vapor deposition (CVD), physical vapor deposition (PVD) or electroplating process. The conductive material layer is then patterned by a photolithography/etching process to form the conductive layers 58 and 60, also referred to as a conductive path or a trace.

After the forming of the conductive layers 58 and 60, an insulating protective layer 66, also referred to as a solder mask, is coated on the conductive layers 58 and 60 for impact or scrape protection, followed by patterning to expose a portion of the conductive layer 58 and the conductive layer 60. The bonding pads 61 and 62, such as copper, are disposed on the exposed conductive layers 58 and 60, respectively. In FIG. 2A, the insulating protective layer between the conductive layer 60 and the chip 52 is omitted for brevity.

Note that the conductive layer 60, and the trace, is directly disposed under the chip 52, without going around the region where the chip 52 is located. Thus, decreasing the area of the supported board 56 for the conductive path and reducing the dimensions of the semiconductor device package 50. Moreover, the conductive layer 58 is placed at the same level as the conductive layer 60, whereby the conductive layer 58 and 60, respectively extend to an exterior circuit to transmit signals from the chip 52.

FIG. 2B is a cross section of a semiconductor device package 50 according to a second embodiment of the invention. Compared with the first embodiment, the conductive layers in the second embodiment are stacked to form a multilayer on the supported board. The formations and the materials of the similar elements described in the first embodiment will not be provided again for brevity.

Referring to FIG. 2B, the supported board 56 is provided with the conductive layer 60 formed thereon. An insulting layer 68 is then formed on the supported board 56 and covers the conductive layer 60. The conductive layer 58 is formed on the insulating layer 68. Next, an insulating protective layer 66 thereon is coated. After the steps, the support board 56, having double conductive layers (the conductive layer 58 and the conductive layer 60), also referred to as a printed circuit board with a doubled conductive paths, is completed.

Next, the chip 52 is disposed on the supported board 56 having the double conductive layers. The bonding pad 53 is electrically connected to the bonding pad 61, and the bonding pad 54 is electrically connected to the bonding pad 62 via the wire 64 to transmit the signal from the chip 52 to the conductive layers 58 and 60, and further to an exterior circuit (not shown).

The conductive layer 60 is formed directly under the chip 52, rather than around the region where the chip 52 is located. Thus, decreasing the area of the supported board used to support the conductive path. Accordingly, the dimensions of semiconductor device package are reduced. Moreover, the conductive layers are disposed at different levels, thus, short circuiting caused by the conductive layers is avoided.

FIG. 2C is a top view of the semiconductor device package 50 as shown in FIG. 2A. Referring to FIG. 2C, the chip 52 is placed on the supported board 56, wherein the chip's signals are transmitted to the conductive layer 60 (also the trace) via the bonding pad 54, the wire 64 and the bonding pad 62. The signals are then transmitted to an exterior circuit, for example power drivers or address drivers, via the conductive layer 60 under the chip 52. Also, the signal is also transmitted to the exterior circuit via the bonding pad 53, the wire 64, the bonding pad 61 and the conductive layer 58.

In FIG. 2C, the conductive layer 60 is directly extended on the region beneath the chip 52 without going around the chip 52. Thus, decreasing the area of the supported board 56 used to support the conductive path. Accordingly, the dimensions of semiconductor device package are reduced. Moreover, the signal is transmitted via the conductive layer directly under the chip 52, thus shortening the conductive path for a signal.

Referring to FIG. 2D, the conductive path (also the conductive layer 60) under the chip 52 may extend to the exterior circuit in a nonparallel direction to the bonding pad 54 or the bond pad 62. For example, the conductive path can extend to the exterior circuit in a direction perpendicular to the bonding pad 62 to transmit the signal from the chip 52. It is appreciated that the conductive paths in the first and the second embodiments may extend in a similar way to decrease the area of the supported board. Thus, reducing the dimensions of the semiconductor device package.

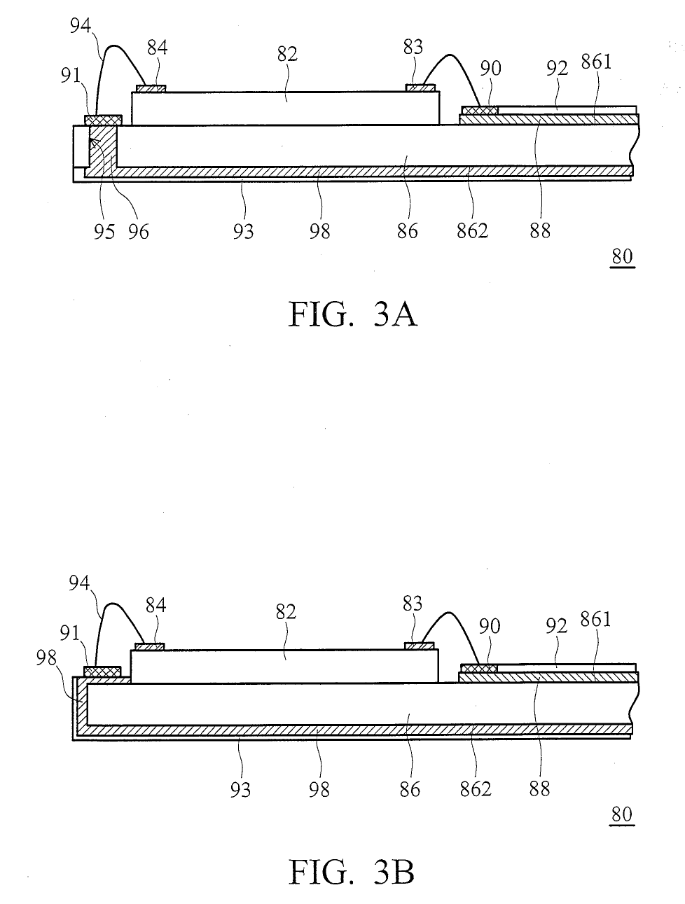

FIGS. 3A and 3B are schematic views of a semiconductor device package 80 according to several embodiments of the invention, in which a chip is disposed on a supported board with two-sided conductive paths. FIG. 3A is a cross section of the semiconductor device package 80 according to a third embodiment of the invention. Referring to FIG. 3A, a supported board 86, having a first surface 861 and a second surface 862 opposite to the first surface 861, is provided. A conductive layer 88 and a conductive layer 98 are formed on the first surface 861 and the second surface 862 of the supported board 86 to electrically connect to the bonding pad 90 and the bonding pad 91, respectively. The conductive layer 98 is electrically connected to the bonding pad 91 through a via hole 96 formed in the supported board 86.

In one embodiment, a conductive material such as copper is disposed on the first surface 861 and the second surface 862 of the supported board 86 by an attaching, bonding or electroplating process. Next, a patterned photoresist (not shown) is formed on the conductive material of the first surface 861, followed forming a hole 95 by a dry-etching step, wherein the hole 95 passes through the conductive material of the first surface 861 and the supported board 86. After the hole 95 has been formed, the hole 95 is filled with a conductive material to form the via hole 96. The conductive materials of the first surface 861 and the second surface 862 are patterned to form the conductive layer 88 and the conductive layer 98. In another embodiment, the hole 95 may be formed by a laser drilling process without the patterned photoresist.

Then, an insulating protective layer 92 and an insulating protective layer 93, respectively, covers the conductive layer 88 and the conductive layer 98 for impact or scrape protection or unnecessary connection. A bonding pad 91 and a boding pad 90 are formed on the first surface 861 of the supported board 86 by a CVD, PVD or electroplating process, accompanied by a photolithography/etching process. The bonding pads are electrically connected to the conductive layer 98 and the conductive layer 88, respectively. Moreover, the insulating layers 92 and 93 may be coated on the conductive layers 88 and 98 by screen-printing, and a portion of the conductive layers 88 and 98 is exposed for connection. After the above-described steps, the supported board 86 with two-sided conductive paths is completed.

In FIG. 3A, a chip 82, having a bonding pad 83 and a boding pad 84 formed thereon, is provided and disposed on the supported board 86 with two-sided conductive paths. The bonding pad 83 is electrically connected to the bonding pad 90, and the bonding pad 84 is electrically connected to the bonding pad 91 via a wire 94. A signal from the chip 82 can be transmitted to the conductive layer 98, which is formed on the second surface 862 of the supported board 86, via the wire 94, the bonding pad 91 and the via hole 96. The signal is then transmitted to an exterior circuit (not shown). Also, the signal from the chip 82 can be transmitted to the conductive layer 88, which is formed on the first surface 861 of the supported board 86, via the wire 94 and the bonding pad 90, and then further to the exterior circuit.

Accordingly, the signal from the chip 82 can be transmitted to the exterior circuit via the conductive paths, which are formed on the first and the second surfaces of the supported board. The formations and materials of the similar elements described in the first embodiment will not be provided again for brevity.

Note that the conductive path is formed directly on the second surface (also referred to as backside) of the supported board. Thus, decreasing the area of the supported board used to support the conductive path. Accordingly, the dimensions of the semiconductor device package are reduced.

FIG. 3B is a cross section of the semiconductor device package 80 according to a fourth embodiment of the invention. In this case, the conductive layer 98 is formed on the second surface 862 of the supported board 86, and is extended on the sidewall of the supported board 86 to the first surface 861 to electrically connect to the bonding pad 91 without the via hole. The formations and materials of the similar elements described in the first embodiment will not be provided again for brevity.

In FIG. 3B, the supported board 86, having the first surface 861 and the second surface 862, is provided. The conductive layer 88 is formed on the first surface 861. The conductive layer 98 is formed on the second surface 862 and extends on the sidewall of the supported board 86 to the first surface 861. Then, the bonding pad 90 and the bonding pad 91 are disposed on the conductive layer 88 and the conductive layer 98 to electrically connect thereto. After the steps, the supported board 86 with two-sided conductive paths is completed.

The chip 82 is placed on the supported board 86 with two-sided conductive paths, and the bonding pad 83 and the bonding pad 84 are electrically connected to the bonding pad 90 and the bonding pad 91 via the wire 94, respectively. A signal from the chip 82 is transmitted to the conductive layer 98 via the wire 94 and the bonding pad 91. The signal is further transmitted to an exterior circuit via the conductive layer 98, which extends on the first surface 861, the sidewall and the second surface 862 of the supported board 86.

Note that the conductive path (also conductive layer 98) is around the sidewall of the supported board 86 and extends on the backside (the second surface 862) of the supported board 86 to an exterior circuit. Thus, increasing utilization efficiency of the supported board used to support the conductive path. Accordingly, the dimensions of the semiconductor device package are reduced.

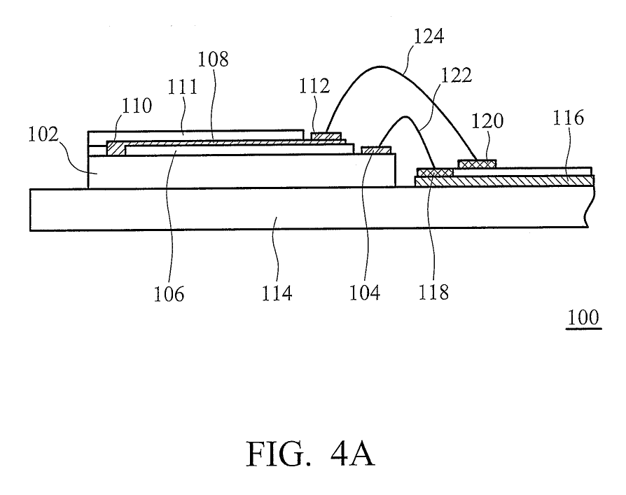

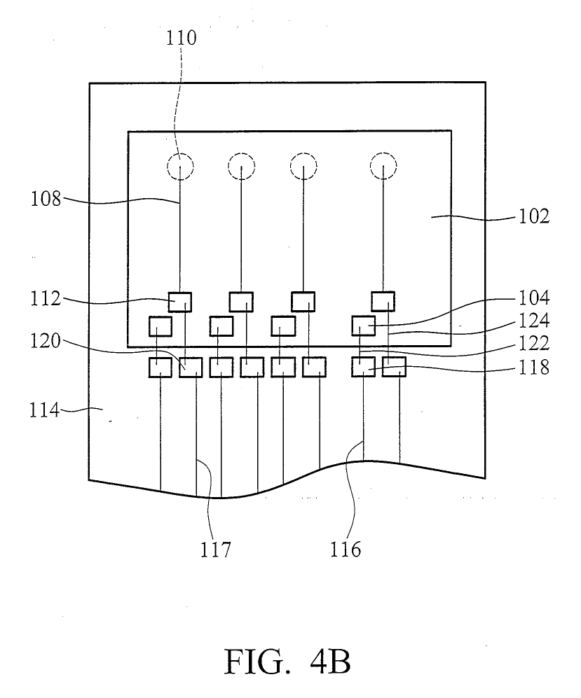

FIGS. 4A and 4B are schematic views of a semiconductor device package 100 according to a fifth embodiment of the invention. Referring to FIG. 4A, a chip 102 is provided with a bonding pad 104 and a bonding pad 112 formed at the same side. In one embodiment, an insulating layer 106 is formed on the chip 102, followed by patterning to form a hole (not symbolized). A conductive material layer such as copper is deposited on the insulating layer 106, and extends to the hole, and then patterned by a photolithography/etching process to form a via hole 110 and a conductive layer 108. The conductive layer 108 is electrically connected to a semiconductor device (not shown) of the chip 102 through the via hole 110. By the above-described steps, the conductive path for signal can be redistributed. An insulating protective layer 111 is coated on the conductive layer 108, followed by patterning to expose a portion of the conductive layer 108. Then, a bonding pad 112 is disposed on the exposed portion of the conductive layer 108. After the steps, a signal from the chip 102 can be transmitted to the same side of the chip 102 through the via hole 110 and the conductive layer 108, and then to an exterior circuit.

The supported board 114, having the bonding pad 118 and the bonding pad 120, is provided and the chip 102 is disposed thereon. Then, using the wire 122 and the wire 124, the bonding pad 104 is electrically connected to the bonding pad 118, and the bonding pad 112 is electrically connected to the bonding pad 120. In an embodiment which is not shown, the bonding pad 112 may be directly formed on the chip 102, and may be at the same level as the conductive layer 108 to electrically connect to the conductive layer 108. The formations and materials of the similar elements described in the first embodiment will not be provided again for brevity.

FIG. 4B is a top view of the semiconductor device package 100 as shown in FIG. 4A. Referring to FIG. 4E, a signal from the chip 102 can be transmitted to the conductive layer 116 (also the conductive path) via the bonding pad 104, the wire 122 and the bonding pad 118. Then, the signal is transmitted to an exterior circuit via the conductive path. Also, a signal from the chip 102 can be transmitted to the bonding pad 112 through the via hole 110 and the conductive layer 108, and transmitted to the conductive layer 117 via the wire 124 and the bonding pad 120, and further to the exterior circuit. In this case, a portion of the signal from the chip 102 can be transmitted to the bonding pad 112 through the via hole 110 and the conductive layer 108 so that the signal can be transmitted to the same side of the chip 102 and then transmitted to the conductive paths via the wire 122 and the wire 124.

The signal of the chip 102 can be transmitted to the same side via the conductive layer 108 so that the conductive path going around the region where the chip 102 is located does not have to be formed. Specifically, a portion of the conductive path for the signal is disposed on the chip rather than the surface of the supported board. Thus, decreasing the area of the supported board 154 used to support the conductive path. Accordingly, the dimensions of the semiconductor device package are reduced.

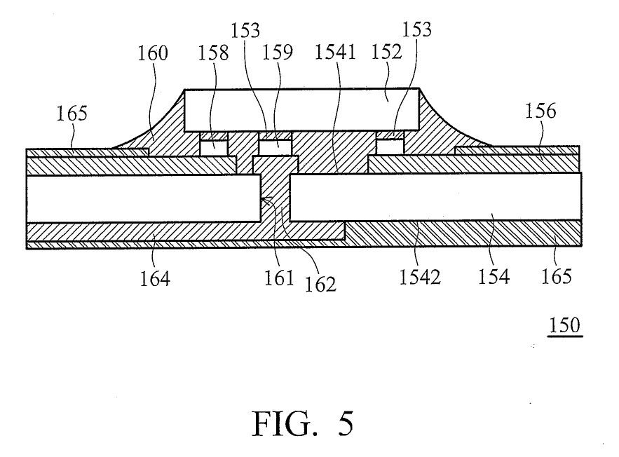

FIG. 5 is a cross section of a semiconductor device package 150 according to a sixth embodiment of the invention. In this case, the invention is applied to an exemplary embodiment of a chip on film (COF). Accordingly, the invention can be applied to any other semiconductor device packages. Referring to FIG. 5, a supported board 154, having a first surface 1541 and a second surface 1542 opposite to the first surface 1541, is provided. Preferably, the supported board 154, also referred to as a base film, is made of a material such as polyimide (PI) or polyester (PET). Moreover, the supported board 154 may be any other flexible soft substrates.

A conductive material such as copper is formed on the first surface 1541 and the second surface 1542 of the supported board 154 by an attaching, bonding or electroplating process. A patterned photoresist (not shown) is formed on the conductive material of the first surface 1541, followed by an etching process to form a hole 161, which is passed through the conductive material of the first surface and the supported board 154. In another embodiment, the hole 161 may also be formed by a laser drilling without the patterned photoresist.

The hole 161 is then filled with a conductive material by electroplating to form a via hole 162 electrically connected to the conductive material of the second surface 1542. The conductive materials of the first surface 1541 and the second surface 1542 are patterned to form the conductive layer 156 and the conductive layer 164. An insulating protective layer 165 covers the conductive layers 156 and 164 for impact or scrape protection or unnecessary connection. After the above-described steps, the supported board with two-sided conductive paths is completed.

In another embodiment, an insulator, serving a flexible supported board, may be coated on a copper foil. When the insulator has become solid, a conductive material is formed on the insulator by an attaching, bonding or electroplating process to form the conductive materials on the two sides of the insulator. Then, the aforementioned opening, filling and patterning steps are performed to complete the supported board with two-sided conductive paths.

In FIG. 5, a chip 152 having a bonding pad 153 formed thereon is provided. A metal bump 158 and a metal bump 159 are disposed on the bonding pad 153 by an electroplating process. Then, the chip 152 is flipped and placed on the first surface 1541 of the supported board 154 so that the metal bump 158 and the metal bump 159 can be electrically connected to the conductive layer 156 and the conductive layer 164, respectively. Following a reflow process, the chip 152 is bonded to the supported board 154. Preferably, the metal bumps 158 and 159 are made of gold (Au) or solder.

After bonding, an encapsulant 160, also referred to as a sealing resin, is disposed between the chip 152 and the supported board 154 to encapsulate the semiconductor device package 150. The metal bump 159 is electrically connected to the conductive layer 164 of the second surface 1542 through the via hole 162.

A signal from the chip 152 can be transmitted to the conductive layer 164 of the backside (the second surface 1542) of the supported board 154 through the metal bump 159 and the via hole 162. Thus, increasing utilization efficiency of the supported board used to support the conductive path. Accordingly, the dimensions of the semiconductor package are reduced.

According to the above-described embodiments, increasing utilization efficiency of the supported board used to support the conductive path. Accordingly, the dimensions of the semiconductor device package are reduced.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device package, comprising:
a supported substrate having a first conductive layer and a second conductive layer formed thereon; and
a chip having a first bonding pad and a second bonding pad formed thereon disposed on the supported substrate, wherein the first bonding pad and the second bonding pad are electrically connecting to the first conductive layer and the second conductive layer, respectively;
wherein the second conductive layer is formed between the chip and the supported substrate.

2. The package as claimed in claim 1, further comprising:
a third bonding pad disposed on the first conductive layer, and electrically connecting to the first bonding pad; and
a fourth bonding pad disposed on the second conductive layer, and electrically connecting to the second bonding pad.

3. The package as claimed in claim 2, further comprising:
a first wire electrically connecting the first bonding pad to the third bonding pad; and
a second wire electrically connecting the second bonding pad to the fourth bonding pad.

4. The package as claimed in claim 1, wherein the first conductive layer and the second conductive layer are located on the same level.

5. The package as claimed in claim 1, further comprising an insulating layer formed between the chip and the supported substrate and covering the second conductive layer.

6. The package as claimed in claim 5, wherein the first conductive layer and the second conductive layer are located on different levels.

7. The package as claimed in claim 2, wherein the second conductive layer extends to an exterior circuit in a nonparallel direction to the fourth bonding pad

8. A semiconductor device package, comprising:
a supported substrate having a first surface and a second surface opposite to the first surface;
a chip having a first bonding pad and a second bond pad formed thereon disposed on the first surface;
a first conductive layer formed on the first surface of the supported substrate, and electrically connecting to the first bonding pad; and
a second conductive layer formed on the second surface of the supported substrate, and electrically connecting to the second bonding pad.

9. The package as claimed in claim 8, further comprising:
a third bonding pad disposed on the first conductive layer;
a fourth bonding pad disposed on the first surface of the supported substrate;
a first wire electrically connecting the third bonding pad to the first bonding pad; and
a second wire electrically connecting the fourth bonding to the second bonding pad.

10. The package as claimed in claim 9, wherein the second conductive layer is formed on the second surface of the supported substrate, and extends on a sidewall of the supported substrate to the first surface to electrically connect to the fourth bonding pad.

11. The package as claimed in claim 9, further comprising a via hole formed in the supported substrate to electrically connect the second conductive layer to the fourth bonding pad.

12. The package as claimed in claim 8, further comprising:
a first metal bump disposed on the first bonding pad; and
a second metal bump disposed on the second bonding pad;
wherein the first metal bump electrically connects to the first conductive layer, and the second metal bump electrically connects to the second conductive layer.

13. The package as claimed in claim 12, further comprising a via hole formed in the supported substrate to electrically connect the second conductive layer to the second metal bump.

14. The package as claimed in claim 12, further comprising an encapsulant disposed between the chip and the supported substrate.

15. A semiconductor device package, comprising:
a supported substrate having a first conductive layer and a second conductive layer formed thereon;
a chip having a semiconductor device formed therein disposed on the supported substrate;
a third conductive layer formed on the chip, and electrically connecting to the semiconductor device;
a first bonding pad disposed on the chip, and electrically connecting to the first conductive layer; and
a second bonding pad disposed on the chip, and electrically connecting the second conductive layer to the third conductive layer.

16. The package as claimed in claim 15, further comprising an insulating layer formed on the chip to isolate the third conductive layer from the chip.

17. The package as claimed in claim 16, further comprising a via hole formed in the insulating layer to electrically connect the third conductive layer to the semiconductor device.

18. The package as claimed in claim 15, further comprising:
a third bonding pad disposed on the first conductive layer;
a fourth bonding pad disposed on the second conductive layer;
a first wire electrically connecting the first bonding pad to the third bonding pad, and
a second wire electrically connecting the second bonding pad to the fourth bonding pad.

19. The package as claimed in claim 15, wherein the first bonding pad and the second bonding pad are at the same side of the chip.

20. The package as claimed in claim 15, further comprising an insulating protective layer covering the third conductive layer.
